(19) United States
(12) Patent Application Publication
(10) Pub. No.: US 2026/0204859 A1
(43) Pub. Date: Jul. 16, 2026

(54) LASER CHAMBER, LASER DEVICE, AND ELECTRONIC DEVICE MANUFACTURING METHOD

(71) Applicant: Gigaphoton Inc., Tochigi (JP)

(72) Inventor: Yuto WAKUI, Tochigi (JP)

(73) Assignee: Gigaphoton Inc., Tochigi (JP)

(21) Appl. No.: 19/410,687

(22) Filed: Dec. 5, 2025

(30) Foreign Application Priority Data
Jan. 15, 2025 (JP) 2025-005395

(51) Int. Cl. H01S 3/038; G03F 7/00

(52) U.S. Cl. CPC H01S 3/0384; G03F 7/70025; G03F 7/7095

(57) ABSTRACT

A laser chamber includes a container configured to be filled with a laser gas, a first electrode arranged in the container, a second electrode arranged at a position closer to an inner wall of the container than the first electrode while facing the first electrode, and a preionization device arranged on at least one lateral side of the first electrode. Here, the preionization device includes a dielectric pipe, a preionization inner electrode arranged in the dielectric pipe, a preionization outer electrode arranged in contact with outside of the dielectric pipe, an electrically insulating tube inserted between the dielectric pipe and the preionization inner electrode at an end part of the dielectric pipe in a longitudinal direction, and an electrically insulating fixing base that fixes the dielectric pipe at the end part of the dielectric pipe in the longitudinal direction and makes point contact with the dielectric pipe.

### CROSS-REFERENCE TO RELATED APPLICATIONS

The present application claims the benefit of Japanese Patent Application No. 2025-005395, filed on Jan. 15, 2025, the entire contents of which are hereby incorporated by reference.

### BACKGROUND

### 1. Technical Field

The present disclosure relates to a laser chamber, a laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. In the following, a gas laser device with a narrowed spectral line width is referred to as a line narrowing gas laser device.

### LIST OF DOCUMENTS

### Patent Documents

Patent Document 1: International Publication No. WO2023/181677

Patent Document 2: Japanese Patent Application Publication No. 2007-250992

Patent Document 3: International Publication No. WO1994/009536

### SUMMARY

A laser chamber according to an aspect of the present disclosure includes a container configured to be filled with a laser gas, a first electrode arranged in the container, a second electrode arranged at a position closer to an inner wall of the container than the first electrode while facing the first electrode, and a preionization device arranged on at least one lateral side of the first electrode. Here, the preionization device includes a dielectric pipe, a preionization inner electrode arranged in the dielectric pipe, a preionization outer electrode arranged in contact with outside of the dielectric pipe, an electrically insulating tube inserted between the dielectric pipe and the preionization inner electrode at an end part of the dielectric pipe in a longitudinal direction, and an electrically insulating fixing base that fixes the dielectric pipe at the end part of the dielectric pipe in the longitudinal direction and makes point contact with the dielectric pipe.

A laser device according to another aspect of the present disclosure includes an optical resonator, and a laser chamber arranged so that an optical path of the optical resonator passes therethrough. Here, the laser chamber includes a container configured to be filled with a laser gas, a first electrode arranged in the container, a second electrode arranged at a position closer to an inner wall of the container than the first electrode while facing the first electrode, and a preionization device arranged on at least one lateral side of the first electrode. The preionization device includes a dielectric pipe, a preionization inner electrode arranged in the dielectric pipe, a preionization outer electrode arranged in contact with outside of the dielectric pipe, an electrically insulating tube inserted between the dielectric pipe and the preionization inner electrode at an end part of the dielectric pipe in a longitudinal direction, and an electrically insulating fixing base that fixes the dielectric pipe at the end part of the dielectric pipe in the longitudinal direction and makes point contact with the dielectric pipe.

An electronic device manufacturing method according to another aspect of the present disclosure includes generating laser light using a laser device, outputting the laser light to an exposure apparatus, and exposing a photosensitive substrate to the laser light in the exposure apparatus to manufacture an electronic device. Here, the laser device includes an optical resonator, and a laser chamber arranged so that an optical path of the optical resonator passes therethrough. The laser chamber includes a container configured to be filled with a laser gas, a first electrode arranged in the container, a second electrode arranged at a position closer to an inner wall of the container than the first electrode while facing the first electrode, and a preionization device arranged on at least one lateral side of the first electrode. The preionization device includes a dielectric pipe, a preionization inner electrode arranged in the dielectric pipe, a preionization outer electrode arranged in contact with outside of the dielectric pipe, an electrically insulating tube inserted between the dielectric pipe and the preionization inner electrode at an end part of the dielectric pipe in a longitudinal direction, and an electrically insulating fixing base that fixes the dielectric pipe at the end part of the dielectric pipe in the longitudinal direction and makes point contact with the dielectric pipe.

### BRIEF DESCRIPTION OF THE DRAWINGS

Embodiments of the present disclosure will be described below merely as examples with reference to the accompanying drawings.

FIG. 1 is a view schematically showing the configuration of a gas laser device according to a comparative example.

FIG. 2 is a sectional view of a chamber and a pulse power module of the gas laser device according to the comparative example as viewed from a Z direction.

FIG. 3 is a sectional view showing the structure of an end part of a preionization device in a longitudinal direction according to the comparative example.

FIG. 4 is a sectional view taken along line 4-4 of FIG. 3.

FIG. 5 is a diagram showing a simulation result of the electric field strength on an inner surface of a dielectric pipe of the comparative example.

FIG. 6 is a diagram showing the configuration of an end part of the preionization device in the longitudinal direction according to a first embodiment.

FIG. 7 is a sectional view taken along line 7-7 of FIG. 6.

FIG. 8 is an enlarged view of a point contact portion of an electrically insulating fixing base of the first embodiment.

FIG. 9 is an enlarged view showing another example of the point contact portion of the electrically insulating fixing base.

FIG. 10 is a diagram showing a simulation result of the electric field strength on the inner surface of the dielectric pipe of the first embodiment.

FIG. 11 is a diagram schematically showing the configuration of an exposure apparatus.

### DESCRIPTION OF EMBODIMENTS

### <Contents>

1. Overview of laser device according to comparative example
   1.1 Configuration
   1.2 Operation
   1.3 Configuration of preionization device according to comparative example
   1.4 Problem
2. First embodiment
   2.1 Configuration
   2.2 Operation
   2.3 Effect
3. Electronic device manufacturing method
4. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Overview of Laser Device According to Comparative Example

### 1.1 Configuration

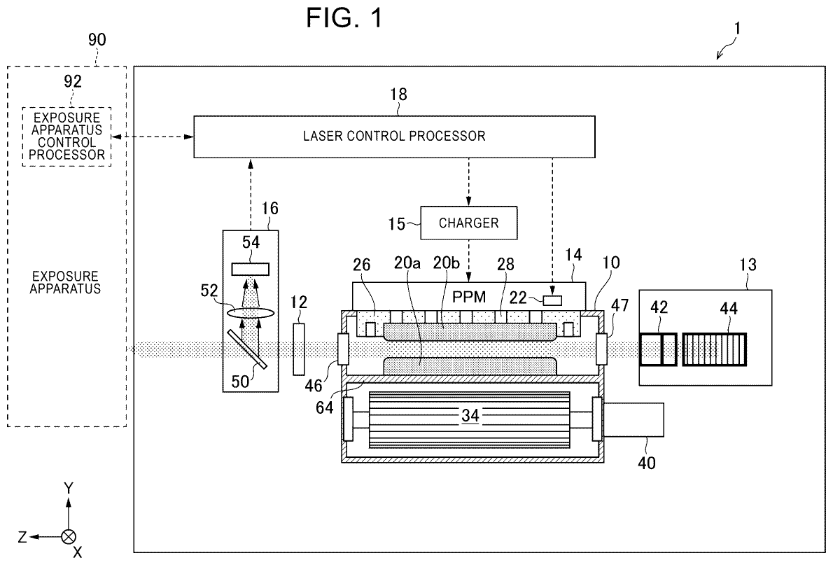

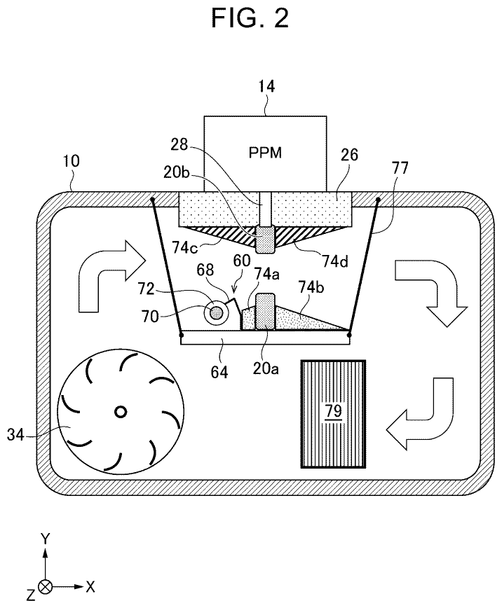

FIGS. 1 and 2 are views schematically showing the configuration of a laser device 1 according to a comparative example. FIG. 2 is a sectional view of a laser chamber 10 and a pulse power module (PPM) 14 shown in FIG. 1 as viewed from a Z direction. In FIG. 1, a travel direction of laser light output from the laser device 1 is referred to as the Z direction. An X direction and a Y direction are directions orthogonal to the Z direction and orthogonal to each other. A direction orthogonal to the plane of FIG. 1 is referred to as the X direction. In the following drawings, the X direction, the Y direction, and the Z direction are similar to those shown in FIG. 1. The comparative example of the present disclosure is an example recognized by the applicant as known only by the applicant, and is not a publicly known example admitted by the applicant.

The laser device 1 is a discharge-excitation-type gas laser device including the laser chamber 10, an output coupling mirror (OC) 12, a line narrowing module (LNM) 13, the PPM 14, a charger 15, a monitor module 16, and a laser control processor 18.

The laser chamber 10 is a container filled with a laser gas, and includes a pair of main electrodes 20a, 20b, an electrically insulating block 26, a cross flow fan 34, a motor 40, windows 46, 47, a preionization device 60, a main electrode plate 64, guides 74a, 74b, 74c, 74d, a return plate 77, and a heat exchanger 79.

The laser gas is, for example, a mixed gas including an Ar gas or a Kr gas as a rare gas, an F₂ gas as a halogen gas, and an Ne gas or an He gas as a buffer gas.

The main electrode 20a is arranged to face the main electrode 20b. The main electrode 20b is arranged closer to an inner wall of the laser chamber 10 than the main electrode 20a. The electrically insulating block 26 insulates the main electrode 20b from the PPM 14 and supports the main electrode 20b.

The cross flow fan 34 is rotated by a drive force of the motor 40 to circulate the laser gas in the laser chamber 10.

The preionization device 60 includes a preionization outer electrode 68, a preionization inner electrode 70, and a dielectric pipe 72. The preionization outer electrode 68 is fixed to the main electrode 20a via the guide 74a, and is electrically connected to the main electrode 20a. An end part of the preionization outer electrode 68 is in contact with the outside of the dielectric pipe 72. The preionization outer electrode 68 is a conductor, and the material of the preionization outer electrode 68 is, for example, copper or brass. Here, the preionization outer electrode 68 may be directly fixed to the main electrode 20a.

The preionization inner electrode 70 is arranged inside the dielectric pipe 72. The preionization inner electrode 70 is a conductor, and the material of the preionization inner electrode 70 is, for example, copper or brass.

The material of the dielectric pipe 72 is, for example, alumina ceramic (Al₂O₃) or sapphire. The guide 74a and the guide 74b are arranged to sandwich the main electrode 20a, and the guide 74c and the guide 74d are arranged to sandwich the main electrode 20b. The guides 74a, 74b, 74c, 74d each have a shape that guides the laser gas from the cross flow fan 34 to efficiently flow between the main electrodes 20a, 20b (hereinafter referred to as the “inter-main-electrode space”).

The main electrode plate 64 is a conductor, and the material of the main electrode plate 64 is, for example, aluminum or brass. The return plate 77 is a conductor, and the material of the return plate 77 is, for example, aluminum, copper, or brass. The return plate 77 electrically connects the main electrode plate 64 and the laser chamber 10.

Although FIG. 2 shows an example in which the preionization device 60 is arranged on the left side of the main electrode 20a, the preionization device 60 is only required to be arranged on at least one lateral side of the main electrode 20a, and may be arranged on both sides with the main electrode 20a interposed therebetween.

The PPM 14 includes a charging capacitor (not shown) and a switch 22. The charger 15 is connected to the charging capacitor of the PPM 14. The PPM 14 is connected to the main electrode 20b via a feedthrough 28. The PPM 14 is connected such that, when the switch 22 is turned ON, charges stored in the charging capacitor transitions to the main electrodes 20a, 20b, the preionization outer electrode 68, and the preionization inner electrode 70 in the laser chamber 10.

The OC 12 and the LNM 13 together configure an optical resonator. The laser chamber 10 is arranged on the optical path of the optical resonator. Light in the optical resonator is transmitted through the window 46 and the window 47.

The OC 12 is a partial reflection mirror coated with a multilayer film that reflects a part of the laser light generated in the laser chamber 10 and transmits the other part. The LNM 13 includes a prism 42 for expanding a beam and a grating 44. The grating 44 is arranged in the Littrow arrangement so that the incident angle and the diffraction angle are the same.

The monitor module 16 includes a beam splitter 50 arranged on the optical path of the laser light output from the OC 12, a light concentrating lens 52, and an optical sensor 54.

The laser control processor 18 functions as a control device of the laser device 1. The laser control processor 18 is a processing device including a storage device in which a control program is stored and a central processing unit (CPU) that executes the control program. The laser control processor 18 is specifically configured or programmed to perform various processes included in the present disclosure. The storage device is a non-transitory computer readable medium that is a tangible object, and includes, for example, a memory that is a main storage device and a storage that is an auxiliary storage device. The computer readable medium may be, for example, a semiconductor memory, a hard disk drive (HDD) device, a solid state drive (SSD) device, or a combination thereof. The laser control processor 18 is electrically connected to an exposure apparatus control processor 92 of the exposure apparatus 90, for example.

The main electrode 20a is an example of the “first electrode” in the present disclosure, and the main electrode 20b is an example of the “second electrode” in the present disclosure. The main electrode plate 64 is an example of the “conductor plate” in the present disclosure.

### 1.2 Operation

The laser control processor 18 controls the motor 40 to rotate the cross flow fan 34. Accordingly, the laser gas circulates in the laser chamber 10 in the order of the cross flow fan 34, the inter-main-electrode space, and the heat exchanger 79.

The laser control processor 18 sets a predetermined charge voltage to the charger 15 so as to obtain a target pulse energy, and transmits an oscillation trigger to the PPM 14. The charging capacitor in the PPM 14 is charged with the predetermined charge voltage. When the switch 22 is operated in synchronization with the oscillation trigger, the charges stored in the charging capacitor are transferred to the main electrodes 20a, 20b, the preionization outer electrode 68, and the preionization inner electrode 70. When the charges are transferred, a voltage between the main electrodes 20a, 20b and voltages at the preionization outer electrode 68 and the preionization inner electrode 70 increase.

As a result, corona discharge occurs between the preionization outer electrode 68 and the dielectric pipe 72, and ultraviolet rays are generated. Then, the laser gas at the inter-main-electrode space is preionized by the irradiation of the ultraviolet rays, and main discharge occurs at the inter-main-electrode space.

The laser gas is excited by the main discharge, and laser oscillation occurs in the optical resonator configured by the OC 12 and the LNM 13. At this time, the spectral line width is narrowed by the prism 42 and the grating 44 in the LNM 13, and the line-narrowed pulse laser light is output from the OC 12. The wavelength of the pulse laser light is, for example, a wavelength in the ultraviolet range from 150 nm to 380 nm.

Further, the laser gas in the laser chamber 10 is heated by the main discharge. The heated laser gas is cooled by cooling water flowing in the heat exchanger 79 while passing through the heat exchanger 79.

The pulse laser light output from the OC 12 enters the monitor module 16, and a part thereof is reflected by the beam splitter 50 and enters the optical sensor 54 via the light concentrating lens 52. Then, the pulse energy is detected by the optical sensor 54. The pulse laser light transmitted through the beam splitter 50 is output from the laser device 1.

Here, the laser device 1 may have a configuration in which a high reflection mirror is arranged instead of the LNM 13, and may output natural oscillation pulse laser light whose spectral line width is not line-narrowed.

### 1.3 Configuration of Preionization Device According to Comparative Example

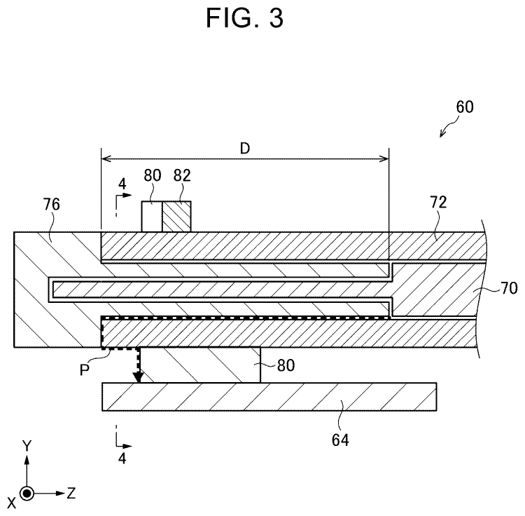

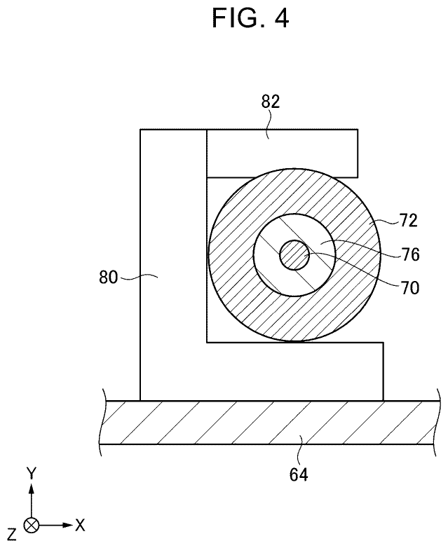

FIGS. 3 and 4 are sectional views showing the structure of an end part of the preionization device 60 in a longitudinal direction according to the comparative example. FIG. 4 is a sectional view taken along line 4-4 of FIG. 3.

The preionization device 60 includes an electrically insulating tube 76, an electrically insulating fixing base 80, and an electrically insulating fixing angle 82.

The dielectric pipe 72 is sandwiched and fixed at an end part thereof in the longitudinal direction by the electrically insulating fixing base 80 and the electrically insulating fixing angle 82. The electrically insulating fixing angle 82 is fixed to the electrically insulating fixing base 80. The electrically insulating fixing base 80 is fixed to the main electrode plate 64. The material of the electrically insulating fixing base 80 and the electrically insulating fixing angle 82 is, for example, alumina ceramic.

The electrically insulating tube 76 is inserted between the dielectric pipe 72 and the preionization inner electrode 70. The electrically insulating tube 76 covers an end part of the preionization inner electrode 70 and closes the end of the dielectric pipe 72. The reason for using the electrically insulating tube 76 is to secure an insulation distance between the preionization inner electrode 70 to which a high voltage is applied and the main electrode plate 64 having a ground potential. In the case of the structure shown in FIG. 3, a path indicated by a thick dotted line arrow in FIG. 3 is assumed as a short-circuit path P leading from the preionization inner electrode 70 in the dielectric pipe 72 to the main electrode plate 64.

Here, a length D from an end of the electrically insulating tube 76 on the preionization inner electrode 70 side to the end of the dielectric pipe 72 is defined as a length for securing the insulation distance. In the region of the length D for securing the insulation distance in FIG. 3, corona discharge for preionization does not occur.

### 1.4 Problem

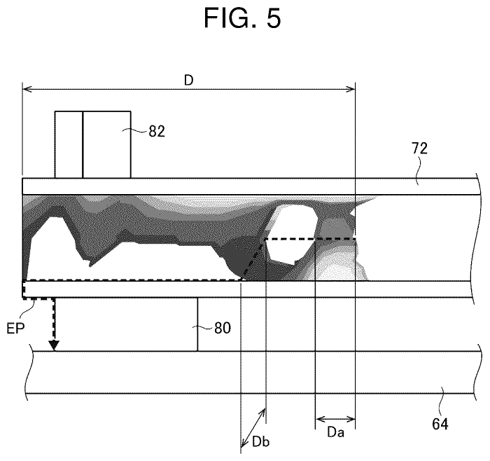

FIG. 5 is a diagram showing a simulation result of the electric field strength on the inner surface of the dielectric pipe 72. In FIG. 5, the distribution of the electric field strength is represented by a heat map. The path indicated by a thick dotted line arrow in FIG. 5 is an estimated short-circuit path EP estimated based on the simulation result. The estimated short-circuit path EP extends from the preionization inner electrode 70 through the inner surface of the dielectric pipe 72 between the L-shaped electrically insulating tube 76 and the dielectric pipe 72, and extends from the end of the dielectric pipe 72 through the surface of the electrically insulating fixing base 80 to the main electrode plate 64.

In the heat map showing the distribution of the electric field strength on the inner surface of the dielectric pipe 72 shown in FIG. 5, the white region has the electric field strength of 3 kV/mm or more, is regarded as a conductor, and is not included in the insulation distance. Therefore, when the white region is large, the length D for securing the insulation distance becomes long. In the case of the simulation result shown in FIG. 5, the insulation distance on the inner surface of the dielectric pipe 72 is the distance (Da+Db) obtained by adding a distance Da and a distance Db in regions where the electric field strength is less than 3 kV/mm. For example, when the distance Da is 6.5 mm and the distance Db is 5.5 mm, the insulation distance of the inner surface of the dielectric pipe 72 is 12.0 mm.

It is desirable to minimize the region where the electric field strength on the inner surface of the dielectric pipe 72 is 3 kV/mm or more, thereby shortening the length D for securing the insulation distance. When the length D for securing the insulation distance is shortened, the length of the region where corona discharge occurs and the length of the region where main discharge occurs can be increased. As a result, the pulse energy of the pulse laser light output from the laser device 1 is improved.

### 2. First Embodiment

### 2.1 Configuration

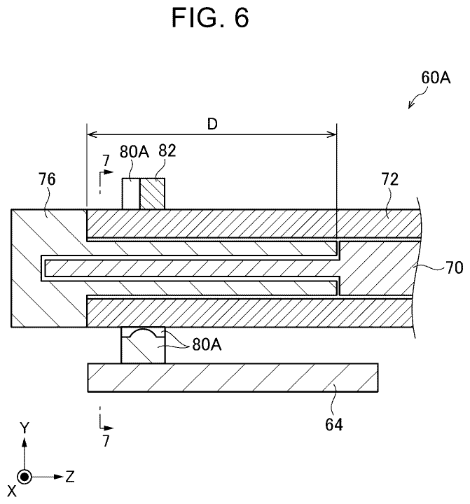

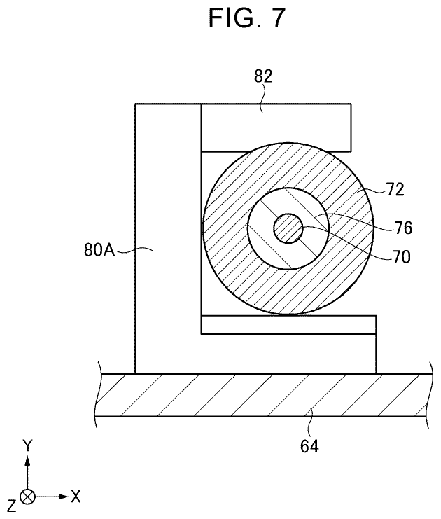

FIG. 6 is a diagram showing the configuration of an end part of a preionization device 60A in the longitudinal direction according to a first embodiment. FIG. 7 is a sectional view taken along line 7-7 of FIG. 6. The configuration shown in FIGS. 6 and 7 will be described in terms of differences from that shown in FIGS. 3 and 4.

The preionization device 60A is different from the preionization device 60 in that an electrically insulating fixing base 80A is arranged instead of the electrically insulating fixing base 80. In the electrically insulating fixing base 80A, among contact portions with the dielectric pipe 72, the contact portion closest to the main electrode plate 64 having the ground potential is a curved surface that makes point contact.

The electrically insulating fixing base 80A includes a first contact portion in contact with a lower portion of the dielectric pipe 72 in the Y direction, and a second contact portion in contact with a side portion of the dielectric pipe 72 in the X direction. Further, the electrically insulating fixing angle 82 includes a third contact portion in contact with an upper portion of the dielectric pipe 72 in the Y direction. Among these contact portions, the contact portion closest to the main electrode plate 64 is the first contact portion.

The first contact portion of the electrically insulating fixing base 80A is formed of a convex curved surface and makes point contact with the dielectric pipe 72. Not only may the first contact portion be configured to make point contact, but other contact portions may also be configured with curved surfaces to make point contact. Here, point contact refers to a contact having a contact area of 1 mm² or less. A convex portion of the electrically insulating fixing base 80A in point contact with the dielectric pipe 72 may be referred to as a “point contact portion” of the electrically insulating fixing base 80A.

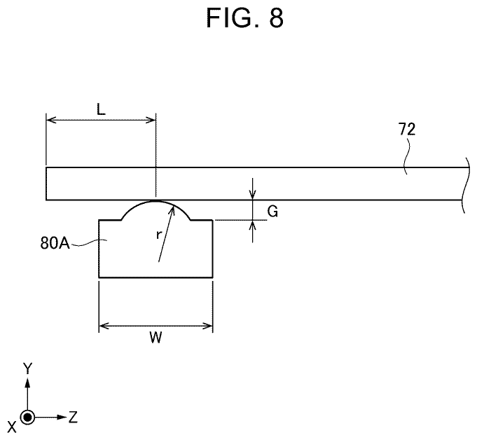

FIG. 8 is an enlarged view of the point contact portion of the electrically insulating fixing base 80A. A cross-sectional shape of a YZ cross-section of the point contact portion of the electrically insulating fixing base 80A includes an arc. A radius of curvature r of the arc is preferably 2 mm or more and 5 mm or less. Further, it is preferable that non-arc parts, which are regions other than the arc in the cross-sectional shape of the YZ cross-section of the electrically insulating fixing base 80A, are configured to be separated from the dielectric pipe 72 by a distance G of 1 mm or more.

When the distance G between the electrically insulating fixing base 80A and the dielectric pipe 72 in the Y direction is 1 mm or more, it is possible to reduce the region where the electric field strength is 3 kV/mm or more on the inner surface of the dielectric pipe 72.

A width W of the electrically insulating fixing base 80A in the Z direction is preferably 5 mm or more and 10 mm or less. By reducing the width W of the electrically insulating fixing base 80A, it is possible to reduce the region where the electric field strength is 3 kV/mm or more on the inner surface of the dielectric pipe 72.

A length L from the position of point contact between the electrically insulating fixing base 80A and the dielectric pipe 72 to the end of the dielectric pipe 72 is preferably 4 mm or more and 15 mm or less.

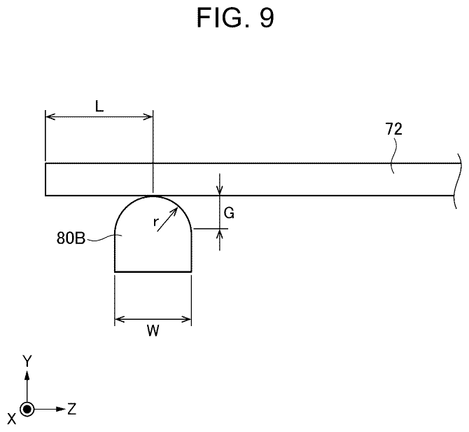

FIG. 8 shows a cross-sectional shape having a shoulder portion parallel to an XZ plane and extending outward from a curved surface portion including the arc that makes point contact of an electrically insulating fixing base 80A. However, the shape of the point contact portion in the electrically insulating fixing base 80A is not limited to the example shown in FIG. 8, and may be a shape without shoulders in the cross-sectional shape of the YZ cross section, for example, as an electrically insulating fixing base 80B shown in FIG. 9.

That is, the cross-sectional shape of the electrically insulating fixing base 80B may have a side surface that is parallel to the Y direction from the start point or the end point of the arc portion. The radius of curvature r of the arc portion of the electrically insulating fixing base 80B is preferably 2 mm or more and 5 mm or less. Here, an example in which the arc portion is a semicircle is shown in FIG. 9, but the arc portion may be smaller than a semicircle.

Preferable conditions of the distance G, the width W, and the length L of the electrically insulating fixing base 80B are similar to those of the electrically insulating fixing base 80A.

It is preferable that the point contact portion of the electrically insulating fixing base 80A or 80B has a surface having a curvature in the longitudinal direction of the dielectric pipe 72, and the contact point is present on the surface having the curvature. However, the shape of the point contact portion of the electrically insulating fixing base 80A or 80B is not limited to a partial cylinder shape which is a part of a side surface of a cylinder having an axis in a direction perpendicular to the longitudinal direction of the dielectric pipe 72, and may be another shape capable of realizing point contact, such as a part of a spherical surface or a ridge of a triangular prism.

The material of the electrically insulating fixing angle 82 and the electrically insulating fixing base 80A, 80B is, for example, alumina ceramic.

The preionization device 60A is arranged in the laser chamber 10 instead of the preionization device 60 according to the comparative example. Other configurations are similar to those of the laser device 1 according to the comparative example.

### 2.2 Operation

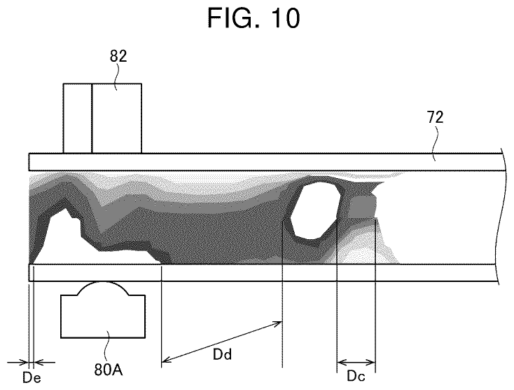

FIG. 10 is a diagram showing a simulation result of the electric field strength on the inner surface of the dielectric pipe 72 of the preionization device 60A according to the first embodiment.

As is apparent from comparison of FIG. 10 and FIG. 5, in the preionization device 60A, the large region in which the electric field strength is 3 kV/mm or more on the inner surface of the dielectric pipe 72 is small. In the preionization device 60A, the insulating distance of the inner surface of the dielectric pipe 72 is a distance obtained by adding a distance Dc, a distance Dd, and a distance De of regions where the electric field strength is less than 3 kV/mm. According to the simulation result, the distances Dc, Dd, De are 6.5 mm, 16.5 mm, 1.0 mm, respectively. Therefore, the insulation length on the inner surface of the dielectric pipe 72 is 24.0 mm, which is 12.0 mm longer than that of the preionization device 60 according to the comparative example.

Operation of the laser device 1 including the preionization device 60A according to the first embodiment may be similar to operation of the laser device 1 according to the comparative example.

### 2.3 Effect

According to the preionization device 60A of the first embodiment, the insulation length on the inner surface of the dielectric pipe 72 is longer than that of the preionization device 60 of the comparative example. Therefore, in the preionization device 60A, the length D for securing the insulation length can be made shorter than that of the preionization device 60.

As a result, in the laser device 1 according to the first embodiment, the length of the region where corona discharge occurs and the length of the region where main discharge occurs can be increased, which leads to improvement in the pulse energy of the pulse laser light output from the laser device 1.

Here, the simulation result shown in FIG. 10 is a case in which the contact portion between the dielectric pipe 72 closest to the main electrode plate 64 having the ground potential and the electrically insulating fixing base 80A makes point contact with a curved surface, but even when another contact portion makes point contact with a curved surface, the effect of shortening the length D for securing the insulation distance can be expected.

### 3. Electronic Device Manufacturing Method

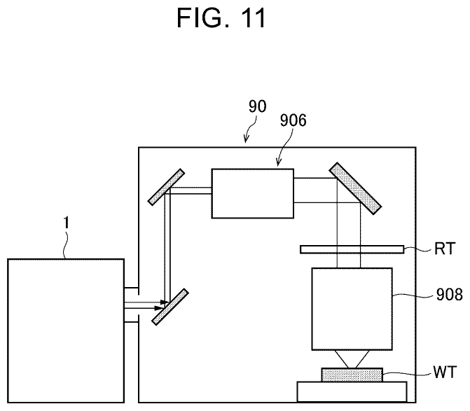

FIG. 11 is a diagram schematically showing the configuration of the exposure apparatus 90. In FIG. 11, the exposure apparatus 90 includes an illumination optical system 906 and a projection optical system 908. The illumination optical system 906 illuminates a reticle pattern of a reticle (not shown) arranged on a reticle stage RT with laser light incident from the laser device 1. The projection optical system 908 causes the laser light transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 90 synchronously translates the reticle stage RT and the workpiece table WT to expose the workpiece to the laser light reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure.

### 4. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. A laser chamber comprising:
a container configured to be filled with a laser gas;
a first electrode arranged in the container;
a second electrode arranged at a position closer to an inner wall of the container than the first electrode while facing the first electrode; and
a preionization device arranged on at least one lateral side of the first electrode,
the preionization device including:
a dielectric pipe;
a preionization inner electrode arranged in the dielectric pipe;
a preionization outer electrode arranged in contact with outside of the dielectric pipe;
an electrically insulating tube inserted between the dielectric pipe and the preionization inner electrode at an end part of the dielectric pipe in a longitudinal direction; and
an electrically insulating fixing base that fixes the dielectric pipe at the end part of the dielectric pipe in the longitudinal direction and makes point contact with the dielectric pipe.

2. The laser chamber according to claim 1,
wherein the preionization device includes a conductor plate that fixes the first electrode and the electrically insulating fixing base, and
among contact portions between the electrically insulating fixing base and the dielectric pipe, a contact portion closest to the conductor plate makes the point contact.

3. The laser chamber according to claim 1,
wherein a position of the point contact is in a range of 4 mm or more and 15 mm or less from an end of the dielectric pipe.

4. The laser chamber according to claim 1,
wherein the electrically insulating fixing base has a surface having a curvature in the longitudinal direction of the dielectric pipe, and makes the point contact with the dielectric pipe on the surface having the curvature.

5. The laser chamber according to claim 1,
wherein a cross-sectional shape of the electrically insulating fixing base at a position of the point contact includes an arc.

6. The laser chamber according to claim 5,
wherein a radius of curvature of the arc is in a range of 2 mm or more and 5 mm or less.

7. The laser chamber according to claim 5,
wherein a part of the cross-sectional shape other than the arc is separated from the dielectric pipe by 1 mm or more.

8. The laser chamber according to claim 1,
wherein a material of the electrically insulating fixing base is alumina ceramic.

9. A laser device comprising:
an optical resonator; and
a laser chamber arranged so that an optical path of the optical resonator passes therethrough,
the laser chamber including:
a container configured to be filled with a laser gas;
a first electrode arranged in the container;
a second electrode arranged at a position closer to an inner wall of the container than the first electrode while facing the first electrode; and
a preionization device arranged on at least one lateral side of the first electrode, and
the preionization device including:
a dielectric pipe;
a preionization inner electrode arranged in the dielectric pipe;
a preionization outer electrode arranged in contact with outside of the dielectric pipe;
an electrically insulating tube inserted between the dielectric pipe and the preionization inner electrode at an end part of the dielectric pipe in a longitudinal direction; and
an electrically insulating fixing base that fixes the dielectric pipe at the end part of the dielectric pipe in the longitudinal direction and makes point contact with the dielectric pipe.

10. The laser device according to claim 9,
wherein the preionization device includes a conductor plate that fixes the first electrode and the electrically insulating fixing base, and
among contact portions between the electrically insulating fixing base and the dielectric pipe, a contact portion closest to the conductor plate makes the point contact.

11. The laser device according to claim 9,
wherein a position of the point contact is in a range of 4 mm or more and 15 mm or less from an end of the dielectric pipe.

12. The laser device according to claim 9,
wherein the electrically insulating fixing base has a surface having a curvature in the longitudinal direction of the dielectric pipe, and makes the point contact with the dielectric pipe on the surface having the curvature.

13. The laser device according to claim 9,
wherein a cross-sectional shape of the electrically insulating fixing base at a position of the point contact includes an arc.

14. The laser device according to claim 13,
wherein a radius of curvature of the arc is in a range of 2 mm or more and 5 mm or less.

15. The laser device according to claim 13,
wherein a part of the cross-sectional shape other than the arc is separated from the dielectric pipe by 1 mm or more.

16. The laser device according to claim 9,
wherein a material of the electrically insulating fixing base is alumina ceramic.

17. An electronic device manufacturing method, comprising:
generating laser light using a laser device;
outputting the laser light to an exposure apparatus; and
exposing a photosensitive substrate to the laser light in the exposure apparatus to manufacture an electronic device,
the laser device including:
an optical resonator; and
a laser chamber arranged so that an optical path of the optical resonator passes therethrough,
the laser chamber including:
a container configured to be filled with a laser gas;
a first electrode arranged in the container;
a second electrode arranged at a position closer to an inner wall of the container than the first electrode while facing the first electrode; and
a preionization device arranged on at least one lateral side of the first electrode, and
the preionization device including:
a dielectric pipe;
a preionization inner electrode arranged in the dielectric pipe;
a preionization outer electrode arranged in contact with outside of the dielectric pipe;
an electrically insulating tube inserted between the dielectric pipe and the preionization inner electrode at an end part of the dielectric pipe in a longitudinal direction; and
an electrically insulating fixing base that fixes the dielectric pipe at the end part of the dielectric pipe in the longitudinal direction and makes point contact with the dielectric pipe.
